(19) United States
(12) Patent Application Publication
(10) Pub. No.: US 2025/0157911 A1
(43) Pub. Date: May 15, 2025

(54) SEMICONDUCTOR DEVICE AND METHOD OF MOUNTING SEMICONDUCTOR DEVICE

(71) Applicant: Mitsubishi Electric Corporation, Tokyo (JP)

(72) Inventor: Kazuki NISHIDA, Tokyo (JP)

(73) Assignee: Mitsubishi Electric Corporation, Tokyo (JP)

(21) Appl. No.: 18/798,747

(22) Filed: Aug. 8, 2024

(30) Foreign Application Priority Data
Nov. 9, 2023 (JP) 2023-191349

(51) Int. Cl. H01L 23/498; H01L 21/48; H01L 23/00; H01L 23/31; H01L 23/367; H01L 25/18

(52) U.S. Cl. CPC H01L 23/49844; H01L 21/4853; H01L 23/3121; H01L 23/564; H01L 23/367; H01L 23/49866; H01L 24/48; H01L 25/18; H01L 2224/48137; H01L 2224/48245; H01L 2924/1203; H01L 2924/13055; H01L 2924/13091

(57) ABSTRACT

A semiconductor device includes: a semiconductor element; a sealing resin that seals the semiconductor element; and a plurality of terminals that are electrically connected to the semiconductor element, protrude from a first side surface and a second side surface of the sealing resin, and extend to a height position of a second main surface. A heat sink is disposed on a first main surface of the sealing resin, a control board to which the plurality of terminals are electrically connected is disposed on the second main surface of the sealing resin, and the semiconductor device further includes a pair of portions to be joined that protrude from a third side surface and a fourth side surface of the sealing resin, are joined to the control board, and are not electrically connected to the semiconductor element.

### BACKGROUND OF THE INVENTION

### Field of the Invention

The present disclosure relates to a semiconductor device and a method of mounting the semiconductor device.

### Description of the Background Art

In a semiconductor device for home electric appliance and industrial small-capacity motor drive, a transfer mold type and insertion mounting type shape is generally adopted because it is necessary to appropriately dissipate heat generated by the semiconductor device. However, among them, a surface mounting type shape is adopted for small-capacity applications such as a fan motor (see, for example, Japanese Patent Application Laid-Open No. 01-270336). A terminal of a surface mounting type semiconductor device is joined to a substrate by soldering.

In recent years, there has been an increasing demand for reduction in size and cost for a control board of a system on which a semiconductor device for driving a motor is mounted. Therefore, there has been a demand for an increase in output capacity with respect to an external size of the semiconductor device. For this reason, an increase in output capacity and attachment of a heat sink for ensuring heat dissipation are contemplated in a surface mounting type semiconductor device used only for small capacity applications such as a fan motor.

However, when a heat sink is attached to a conventional surface mounting type semiconductor device, a load of a heat sheet is applied to a terminal due to vibration or the like during operation of the system including the control board, and thus the semiconductor device is easily peeled off from the control board.

### SUMMARY

An object of the present disclosure is to provide a technique capable of suppressing peeling of a semiconductor device from a control board due to vibration or the like during operation of a system including the control board.

A semiconductor device according to the present disclosure is a semiconductor device mounted on a control board. The semiconductor device includes a semiconductor element, a sealing resin, and a plurality of terminals. The sealing resin has a first main surface, a second main surface opposed to the first main surface, a first side surface connecting the first main surface and the second main surface, a second side surface connecting the first main surface and the second main surface and opposed to the first side surface, a third side surface connecting the first main surface and the second main surface and located between the first side surface and the second side surface, and a fourth side surface connecting the first main surface and the second main surface and opposed to the third side surface, and seals the semiconductor element. The plurality of terminals are electrically connected to the semiconductor element, protrude from the first side surface and the second side surface of the sealing resin, and extend to a height position of the second main surface. A heat dissipation member is disposed on the first main surface of the sealing resin. A control board to which the plurality of terminals are electrically connected is disposed on the second main surface of the sealing resin. The semiconductor device further includes a plurality of portions to be joined that protrude from the third side surface and the fourth side surface of the sealing resin and are joined to the control board, and are not electrically connected to the semiconductor element.

Separately from the plurality of terminals, the plurality of portions to be joined not electrically connected to the semiconductor element are joined to the control board, so that a joining area between the semiconductor device and the control board increases. As a result, it is possible to suppress peeling of the semiconductor device from the control board due to vibration or the like during operation of the system including the control board.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a perspective top view of a semiconductor device according to a first preferred embodiment;

FIG. 2 is a top view of the semiconductor device according to the first preferred embodiment;

FIG. 3 is a side view of the semiconductor device according to the first preferred embodiment in a state turned upside down;

FIG. 4 is a side view of a state where the semiconductor device according to the first preferred embodiment is turned upside down and joined to a control board and a heat sink;

FIG. 5 is a top view of a copper frame on which portions to be joined included in the semiconductor device according to the first preferred embodiment are formed;

FIG. 6 is a top view of a semiconductor device according to a second preferred embodiment;

FIG. 7 is a side view of a state where the semiconductor device according to the second preferred embodiment is turned upside down and joined to a control board and a heat sink;

FIG. 8 is a top view of a semiconductor device according to a third preferred embodiment;

FIG. 9 is a side view of a state where the semiconductor device according to the third preferred embodiment is turned upside down;

FIG. 10 is a side view of a state where the semiconductor device according to the third preferred embodiment is turned upside down and joined to a control board and a heat sink;

FIG. 11 is a side view of a state where the semiconductor device according to the fourth preferred embodiment is turned upside down; and

FIG. 12 is a side view of a state where the semiconductor device according to the fourth preferred embodiment is turned upside down and joined to a control board and a heat sink.

### DESCRIPTION OF THE PREFERRED EMBODIMENTS

### First Preferred Embodiment

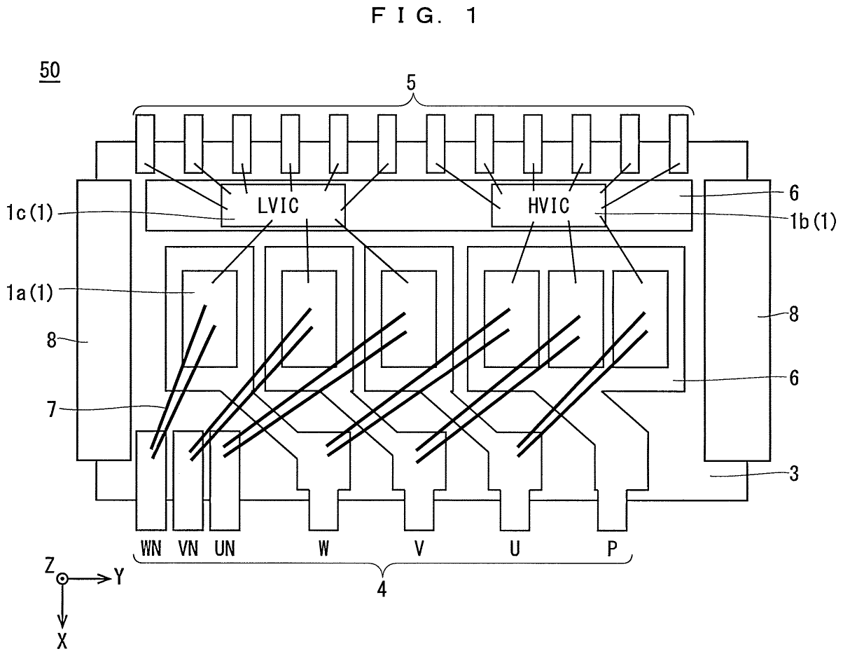

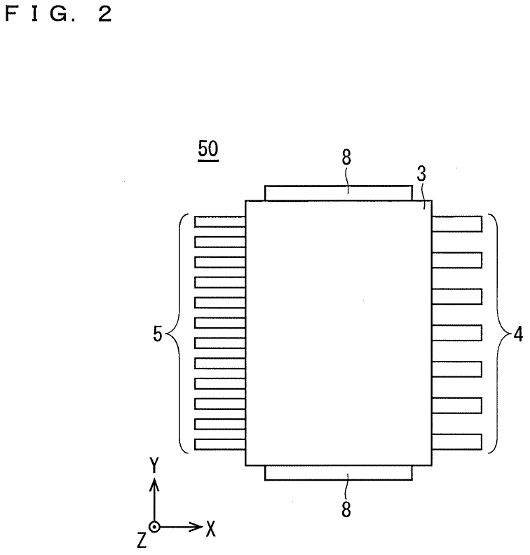

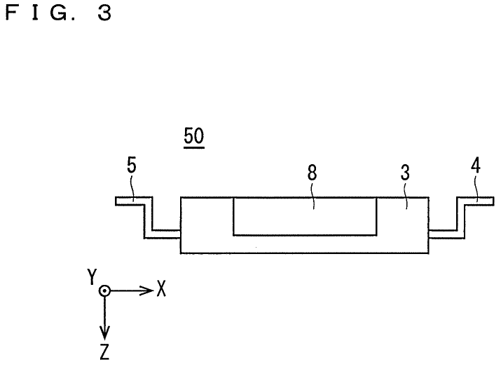

A first preferred embodiment will be described below with reference to the drawings. FIG. 1 is a perspective top view of a semiconductor device 50 according to the first preferred embodiment. FIG. 2 is a top view of the semiconductor device 50 according to the first preferred embodiment. FIG. 3 is a side view of the semiconductor device 50 according to the first preferred embodiment turned in a state turned upside down.

In FIG. 1, an X direction, a Y direction, and a Z direction are orthogonal to one another. The X direction, the Y direction, and the Z direction shown in the following figures are also orthogonal to one another. In the following description, a direction including the X direction and −X direction, which is a direction opposite to the X direction, is also referred to as an “X axis direction”. Moreover, in the following description, a direction including the Y direction and −Y direction, which is a direction opposite to the Y direction is also referred to as a “Y axis direction”. Moreover, in the following description, a direction including the Z direction and −Z direction, which is a direction opposite to the Z direction is also referred to as a “Z axis direction”.

As shown in FIG. 1, the semiconductor device 50 includes a plurality of semiconductor elements 1, a sealing resin 3, a plurality of terminals 4, a plurality of terminals 5, a plurality of frames 6, and a plurality of (a pair of) portions to be joined 8.

The semiconductor elements 1 are electrically connected to each other, and the semiconductor elements 1 and the terminals 4, 5 are electrically connected to each other by wires 7. The plurality of semiconductor elements 1 include six power semiconductor elements 1a, a high voltage integrated circuit (HVIC) 1b, and a low voltage integrated circuit (LVIC) 1c.

The six power semiconductor elements 1a are each an insulated gate bipolar transistor (IGBT), a metal-oxide-semiconductor field effect transistor (MOSFET), or a diode. Among the six power semiconductor elements 1a, three power semiconductor elements 1a on a high voltage side are mounted on one frame 6, and the remaining three power semiconductor elements 1a on a low voltage side are mounted on different three frames 6.

The HVIC1b and the LVIC1c are mounted on the one frame 6. The HVIC1b controls the three power semiconductor elements 1a on the high voltage side. The LVIC1c controls the three power semiconductor elements 1a on the low voltage side.

The plurality of terminals 4 are main terminals and are electrically connected to the six power semiconductor elements 1a. The plurality of terminals 5 are control terminals and are electrically connected to the HVIC1b and the LVIC1c.

As shown in FIGS. 1 and 2, the sealing resin 3 seals the plurality of semiconductor elements 1, the plurality of terminals 4, the plurality of terminals 5, the plurality of frames 6, and the pair of portions to be joined 8 such that a part of the plurality of terminals 4, the plurality of terminals 5, and the pair of portions to be joined 8 are exposed. The sealing resin 3 is formed in a rectangular parallelepiped shape, and has a first main surface (a surface in the Z direction), a second main surface (a surface in a −Z direction) opposed to the first main surface (the surface in the Z direction), a first side surface (a surface in the X direction) connecting the first main surface (the surface in the Z direction) and the second main surface (the surface in the −Z direction), a second side surface (a surface in the −X direction) connecting the first main surface (the surface in the Z direction) and the second main surface (the surface in the −Z direction) and opposed to the first side surface (the surface in the X direction), and a third side surface (a surface in the Y direction) connecting the first main surface (the surface in the Z direction) and the second main surface (the surface in the −Z direction) and located between the first side surface (the surface in the X direction) and the second side surface (the surface in the −X direction), and a fourth side surface (a surface in the −Y direction) connecting the first main surface (the surface in the Z direction) and the second main surface (the surface in the −Z direction) and opposed to the third side surface (the surface in the Y direction).

As shown in FIGS. 1 to 3, the semiconductor device 50 adopts a surface mounting type shape. Base end sides of the plurality of terminals 4 are sealed with the sealing resin 3. Distal end sides of the plurality of terminals 4 protrude in the X direction from the first side surface (the surface in the X direction) of the sealing resin 3 and extend to a height position of the second main surface (the surface in the −Z direction). Further, the distal end portions of the plurality of terminals 4 extend in a direction away from the sealing resin 3 at the height position of the second main surface (the surface in the −Z direction) of the sealing resin 3. In addition, portions of the plurality of terminals 4 protruding from the sealing resin 3, that is, base end portions of the plurality of terminals 4 are located at a height position between the first main surface (the surface in the Z direction) and the second main surface (the surface in the −Z direction) of the sealing resin 3.

Base end sides of the plurality of terminals 5 are sealed with the sealing resin 3. Distal end sides of the plurality of terminals 5 protrude in the −X direction from the second side surface (the surface in the −X direction) of the sealing resin 3 and extend to the height position of the second main surface (the surface in the −Z direction). Further, the distal end portions of the plurality of terminals 5 extend in a direction away from the sealing resin 3 at the height position of the second main surface (the surface in the −Z direction) of the sealing resin 3. In addition, portions of the plurality of terminals 5 protruding from the sealing resin 3, that is, base end portions of the plurality of terminals 5 are located at the height position between the first main surface (the surface in the Z direction) and the second main surface (the surface in the −Z direction) of the sealing resin 3.

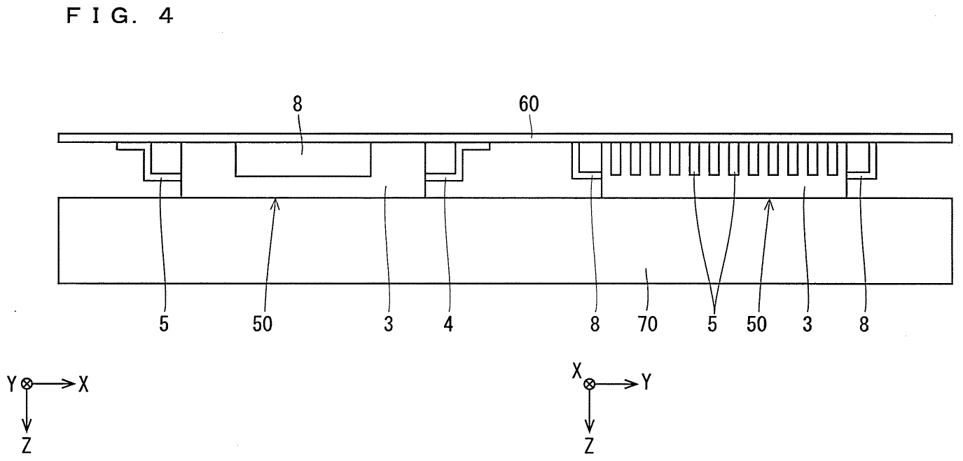

Next, the pair of portions to be joined 8 will be described. FIG. 4 is a side view of a state where the semiconductor device 50 according to the first preferred embodiment is turned upside down and joined to a control board 60 and a heat sink 70. However, in a left view in FIG. 4, the X axis direction is set to a lateral direction so that the joining between the plurality of terminals 4, 5 and the control board 60 can be easily seen, and in a right view in FIG. 4, the Y axis direction is set to the lateral direction so that the joining between the pair of portions to be joined 8 and the control board 60 can be easily seen.

As shown in FIGS. 2 to 4, a width (a length in the X axis direction) of the pair of portions to be joined 8 is formed to be slightly smaller than a length in the X axis direction of the sealing resin 3. The pair of portions to be joined 8 are each formed in an L shape as viewed from the X axis direction. Specifically, base end sides of the pair of portions to be joined 8 extend along the Y axis direction and are sealed with the sealing resin 3, and distal end sides of the pair of portions to be joined 8 protrude in the Y axis direction from the third side surface (the surface in the Y direction) and the fourth side surface (the surface in the −Y direction) of the sealing resin 3 and extend to the height position of the second main surface (the surface in the −Z direction). In addition, the pair of portions to be joined 8 are not electrically connected to the semiconductor elements 1. The pair of portions to be joined 8 are joined to the control board 60 to increase a joining area between the semiconductor device 50 and the control board 60, and also has a function of dissipating heat from the semiconductor elements 1.

Next, as a method of mounting the semiconductor device 50, a method of joining the control board 60 and the heat sink 70 as a heat dissipation member to the semiconductor device 50 will be described.

As shown in FIG. 4, the heat sink 70 is disposed on the first main surface (the surface in the Z direction) of the sealing resin 3 via heat dissipation grease, a resin sheet, or the like (not shown) as a heat transfer member, and the sealing resin 3 and the heat sink 70 are joined by a joining material (not shown) or the like.

The control board 60 to which the plurality of terminals 4, 5 are electrically connected is disposed on the second main surface (the surface in the −Z direction) of the sealing resin 3, and the distal end portions of the plurality of terminals 4, 5 and the pair of portions to be joined 8 are joined to the control board 60. Specifically, the pair of portions to be joined 8 are joined to the control board 60 simultaneously with the plurality of terminals 4, 5 by reflow soldering.

In a state where the control board 60 and the heat sink 70 are joined to the semiconductor device 50, the first main surface (the surface in the Z direction) of the sealing resin 3 is in close contact with the heat sink 70, and the second main surface (the surface in the −Z direction) of the sealing resin 3 is in close contact with the control board 60.

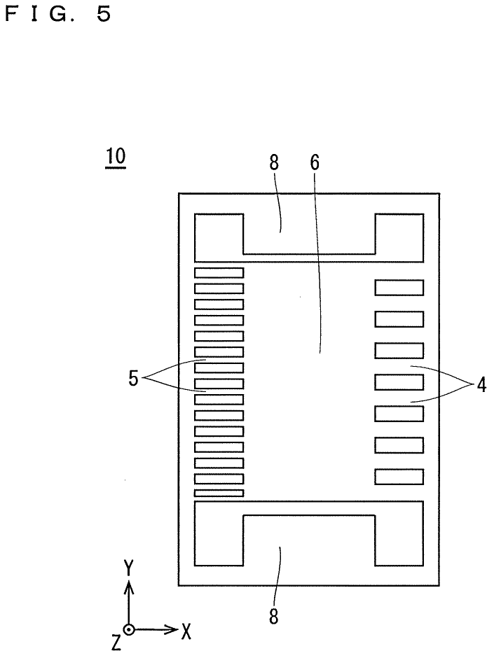

Next, a material of the pair of portions to be joined 8 will be described. FIG. 5 is a top view of a copper frame 10 on which the portions to be joined 8 included in the semiconductor device 50 according to the first preferred embodiment are formed. Note that in FIG. 5, in order to simplify the drawing, the plurality of frames 6 are connected to one.

As shown in FIG. 5, the plurality of terminals 4, 5, the plurality of frames 6, and the pair of portions to be joined 8 are manufactured from one copper frame 10. That is, the material of the plurality of terminals 4, 5 and the pair of portions to be joined 8 are the same copper and have a same thickness.

By subjecting the copper frame 10 to tie bar cutting after molding, the pair of portions to be joined 8 become components independent from the plurality of terminals 4, 5 and the plurality of frames 6. Since copper is a metal having an excellent heat dissipation, a part of the copper frame 10 may be used as the pair of portions to be joined 8 as it is. In addition, the pair of portions to be joined 8 are electrically independent by being completely separated from other portions of the copper frame 10, and potentials of the pair of portions to be joined 8 becomes a floating state. Therefore, the pair of portions to be joined 8 function only for the purpose of joining to the control board 60 and heat dissipation, and even if the pair of portions to be joined 8 come into contact with the control board 60 and the heat sink 70 in a process of mounting the semiconductor device 50, the pair of portions to be joined 8 do not affect electrical characteristics during the operation of the semiconductor elements 1.

As described above, the semiconductor device 50 according to the first preferred embodiment is the semiconductor device 50 mounted on the control board 60. The semiconductor device 50 includes: the semiconductor elements 1; the sealing resin 3 that has the first main surface (the surface in the Z direction), the second main surface (the surface in the −Z direction) opposed to the first main surface (the surface in the Z direction), the first side surface (the surface in the X direction) connecting the first main surface (the surface in the Z direction) and the second main surface (the surface in the −Z direction), the second side surface (the surface in the −X direction) connecting the first main surface (the surface in the Z direction) and the second main surface (the surface in the −Z direction) and opposed to the first side surface (the surface in the X direction), the third side surface (the surface in the Y direction) connecting the first main surface (the surface in the Z direction) and the second main surface (the surface in the −Z direction) and located between the first side surface (the surface in the X direction) and the second side surface (the surface in the −Z direction), and the fourth side surface (the surface in the −Y direction) connecting the first main surface (the surface in the Z direction) and the second main surface (the surface in the −Z direction), and opposed to the third side surface (the surface in the Y direction), and seals the semiconductor elements 1; and the plurality of terminals 4, 5 electrically connected to the semiconductor elements 1, protruding from the first side surface (the surface in the X direction) and the second side surface (the surface in the −X direction) of the sealing resin 3, and extending to the height position of the second main surface (the surface in the −Z direction). The heat sink 70 is disposed on the first main surface (the surface in the Z direction) of the sealing resin 3, the control board 60 to which the plurality of terminals 4, 5 are electrically connected is disposed on the second main surface (the surface in the −Z direction) of the sealing resin 3, and the semiconductor device 50 further includes the pair of portions to be joined 8 that protrude from the third side surface (the surface in the Y direction) and the fourth side surface (the surface in the −Y direction) of the sealing resin 3, are joined to the control board 60, and are not electrically connected to the semiconductor elements 1.

Therefore, separately from the plurality of terminals 4, 5, the pair of portions to be joined 8 not electrically connected to the semiconductor elements 1 are joined to the control board 60, so that the joining area between the semiconductor device 50 and the control board 60 increases. As a result, it is possible to suppress peeling of the semiconductor device 50 from the control board 60 due to vibration or the like during operation of the system including the control board 60.

In addition, with this structure, it is possible to mount the semiconductor device 50 on the heat sink 70 without providing a screw hole for screwing to the heat sink 70 in the semiconductor device 50 as in a conventional insertion mounting type semiconductor device, and it is possible to appropriately dissipate heat while suppressing peeling of the semiconductor device 50 from the control board 60.

In addition, the plurality of terminals 4, 5 extend in the directions away from the sealing resin 3 at the height position of the second main surface (the surface in the −Z direction) of the sealing resin 3. Therefore, since the joining area between the semiconductor device 50 and the control board 60 further increases, it is possible to further suppress peeling of the semiconductor device 50 from the control board 60 due to vibration or the like during operation of the system including the control board 60.

In addition, although the materials of the plurality of terminals 4, 5 and the plurality of portions to be joined 8 are the same, the plurality of portions to be joined 8 are electrically floating. Copper is a material having an excellent heat dissipation, and by using a part of the copper frame 10 as the pair of portions to be joined 8, heat can also be dissipated from the pair of portions to be joined 8 to some extent. In addition, when the copper frame 10 is subjected to the tie bar cutting, the pair of portions to be joined 8 can be electrically independent by completely separating the pair of portions to be joined 8 from the plurality of terminals 4, 5 and the plurality of frames 6. As a result, the pair of portions to be joined 8 become components intended only for heat dissipation and joining, and do not affect the electrical characteristics of the semiconductor device 50.

In addition, portions of the plurality of terminals 4, 5 protruding from the sealing resin 3 are located at the height position between the first main surface (the surface in the Z direction) and the second main surface (the surface in the −Z direction) of the sealing resin 3.

Therefore, when the semiconductor device 50 is disposed on the control board 60 and the heat sink 70 is mounted, the sealing resin 3 serves as a stopper and the heat sink 70 and the plurality of terminals 4, 5 are not in contact with each other, so that it is possible to suppress deformation of the plurality of terminals 4, 5 due to pressing of the heat sink 70. As a result, heat can be appropriately dissipated by maintaining adhesion of the heat dissipation surface (the first main surface) between the heat sink 70 and the sealing resin 3 while maintaining the original shapes of the plurality of terminals 4, 5.

In addition, since the pair of portions to be joined 8 are joined to the control board 60 simultaneously with the plurality of terminals 4, 5 by reflow soldering, the joining area between the semiconductor device 50 and the control board 60 can be increased without changing a mounting method of the conventional semiconductor device as much as possible.

### Second Preferred Embodiment

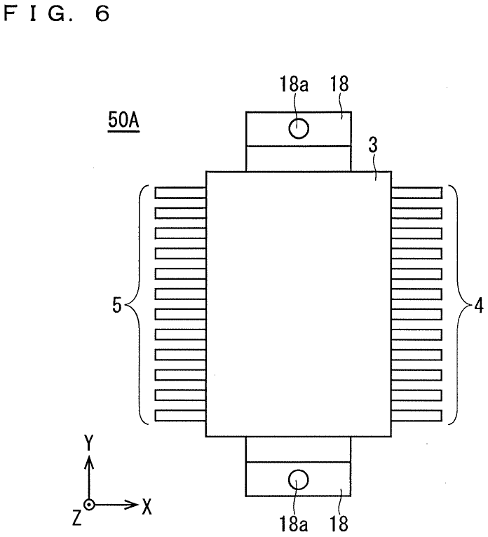

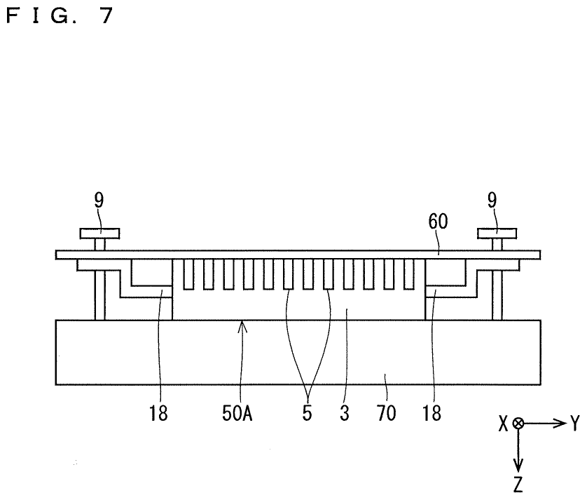

Next, a semiconductor device 50A according to a second preferred embodiment will be described. FIG. 6 is a top view of the semiconductor device 50A according to the second preferred embodiment. FIG. 7 is a side view of a state where the semiconductor device 50A according to the second preferred embodiment is turned upside down and joined to the control board 60 and the heat sink 70. Note that in the second preferred embodiment, the same components as those described in the first preferred embodiment are denoted by the same reference signs, and description thereof is omitted.

As shown in FIGS. 6 and 7, in the second preferred embodiment, the semiconductor device 50A includes a pair of portions to be joined 18 having a different shape from the pair of portions to be joined 8 instead of the pair of portions to be joined 8.

A width (a length in the X-axis direction) of the pair of portions to be joined 18 is formed to be slightly smaller than the length in the X-axis direction of the sealing resin 3. The pair of portions to be joined 18 are each formed in a Z shape as viewed from the X-axis direction. Specifically, base end sides of the pair of portions to be joined 18 extend along the Y axis direction and are sealed with the sealing resin 3, and distal end sides of the pair of portions to be joined 18 protrude in the Y axis direction from the third side surface (the surface in the Y direction) and the fourth side surface (the surface in the −Y direction) of the sealing resin 3, and extend in directions away from the sealing resin 3 to the height position of the second main surface (the surface in the −Z direction). A hole 18a for screwing is provided in a portion extending in the direction away from the sealing resin 3 in each of the pair of portions to be joined 18. In addition, holes (not shown) for screwing are also provided in the heat sink 70, and the control board 60, the pair of portions to be joined 18, and the heat sink 70 are joined by screws 9. The pair of portions to be joined 18 are manufactured from one copper frame 10 as in the case of the first preferred embodiment.

The pair of portions to be joined 18 are not electrically connected to the semiconductor elements 1. The pair of portions to be joined 18 are joined to the control board 60 to increase a joining area between the semiconductor device 50A and the control board 60, and also has a function of dissipating heat from the semiconductor elements 1.

Next, a method of joining the control board 60 and the heat sink 70 to the semiconductor device 50A will be described.

As shown in FIG. 7, the heat sink 70 is disposed as the heat transfer member on the first main surface (the surface in the Z direction) of the sealing resin 3 via the heat dissipation grease or the resin sheet (not shown).

The control board 60 to which the plurality of terminals 4, 5 are electrically connected is disposed on the second main surface (the surface in the −Z direction) of the sealing resin 3, and the distal end portions of the plurality of terminals 4, 5 and the pair of portions to be joined 18 are joined to the control board 60. Specifically, after the plurality of terminals 4, 5 are joined to the control board 60 by reflow soldering, the pair of portions to be joined 18 are joined to the control board 60 and the heat sink 70 by screwing.

As described above, in the semiconductor device 50A according to the second preferred embodiment, the pair of portions to be joined 18 are provided with the holes 18a for screwing, and the pair of portions to be joined 18 are screwed to the control board 60 and both are joined to each other.

In addition, after the plurality of terminals 4, 5 are joined to the control board 60 by reflow soldering, the pair of portions to be joined 18 are joined to the control board 60 by screwing.

Therefore, as in the case of the first preferred embodiment, it is possible to suppress peeling of the semiconductor device 50A from the control board 60 due to vibration or the like during operation of the system including the control board 60. In addition, the semiconductor device 50A and the control board 60 can be more firmly joined than in the case of the first preferred embodiment.

### Third Preferred Embodiment

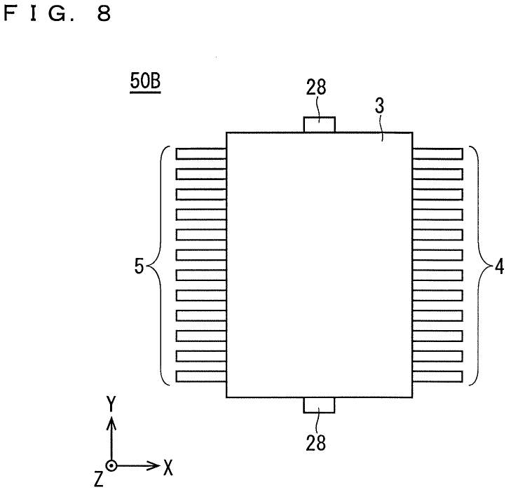

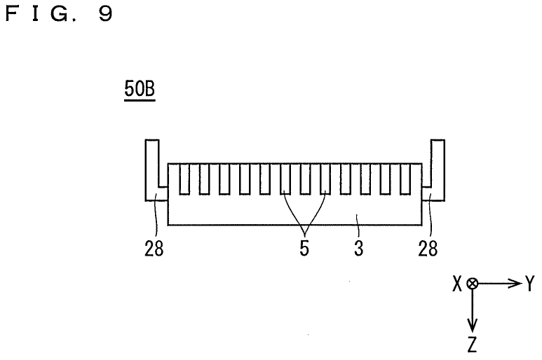

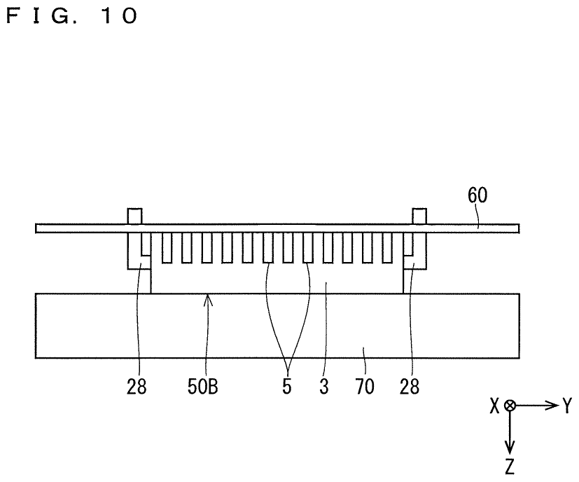

Next, a semiconductor device 50B according to a third preferred embodiment will be described. FIG. 8 is a top view of the semiconductor device 50B according to the third preferred embodiment. FIG. 9 is a side view of a state where the semiconductor device 50B according to the third preferred embodiment is turned upside down. FIG. 10 is a side view of a state where the semiconductor device 50B according to the third preferred embodiment is turned upside down and joined to the control board 60 and the heat sink 70. Note that in the third preferred embodiment, the same components as those described in the first, second preferred embodiments are denoted by the same reference signs, and description thereof is omitted.

As shown in FIGS. 8 to 10, in the third preferred embodiment, the semiconductor device 50B includes a pair of portions to be joined 28 having a different shape from the pair of portions to be joined 8 instead of the pair of portions to be joined 8.

A width (a length in the X-axis direction) of the pair of portions to be joined 28 is formed to be slightly smaller than the pairs of portions to be joined 8, 18 in the first, second preferred embodiments. The pair of portions to be joined 28 are each formed in an L shape as viewed from the X axis direction. Specifically, base end sides of the pair of portions to be joined 28 extend along the Y axis direction and are sealed with the sealing resin 3, and distal end sides of the pair of portions to be joined 28 protrude in the Y axis direction from the third side surface (the surface in the Y direction) and the fourth side surface (the surface in the −Y direction) of the sealing resin 3 and extend to the height position of the second main surface (the surface in the −Z direction). Pins to be inserted into holes (not shown) provided in the control board 60 are provided at the distal end portions of the pair of portions to be joined 28. In other words, the distal end portions of the pair of portions to be joined 28 are each formed in a pin shape. Here, each of the distal end portions of the pair of portions to be joined 28 corresponds to a pin.

The pair of portions to be joined 28 are not electrically connected to the semiconductor elements 1. The pair of portions to be joined 28 are joined to the control board 60 to increase a joining area between the semiconductor device 50B and the control board 60, and also has a function of dissipating heat from the semiconductor elements 1.

Next, a method of joining the control board 60 and the heat sink 70 to the semiconductor device 50B will be described.

As shown in FIG. 10, the heat sink 70 is disposed on the first main surface (the surface in the Z direction) of the sealing resin 3 via the heat dissipation grease, the resin sheet, or the like (not shown) as the heat transfer member, and the sealing resin 3 and the heat sink 70 are joined by a joining material (not shown) or the like.

The control board 60 to which the plurality of terminals 4, 5 are electrically connected is disposed on the second main surface (the surface in the −Z direction) of the sealing resin 3, and the distal end portions of the plurality of terminals 4, 5 and the pair of portions to be joined 28 are joined to the control board 60. Specifically, after the plurality of terminals 4, 5 are joined to the control board 60 by reflow soldering, the pair of portions to be joined 28 are joined to the control board 60 by inserting the pins into the holes (not shown) provided in the control board 60, and then bending the pins, for example, in the Y axis direction. Alternatively, the pair of portions to be joined 28 may be joined to the control board 60 by inserting the pins into the holes provided in the control board 60 and then soldering the pins to a ground terminal (not shown) on the control board 60.

As described above, in the semiconductor device 50B according to the third preferred embodiment, the pins to be inserted into the holes provided in the control board 60 are provided at the distal end portions of the pair of portions to be joined 28.

In addition, after the plurality of terminals 4, 5 are joined to the control board 60 by reflow soldering, the pair of portions to be joined 28 are joined to the control board 60 by inserting the pins into the holes provided in the control board 60, and then bending the pins, or soldering the pins to the ground terminal on the control board 60.

Therefore, as in the case of the first preferred embodiment, it is possible to suppress peeling of the semiconductor device 50B from the control board 60 due to vibration or the like during operation of the system including the control board 60. In addition, the semiconductor device 50B and the control board 60 can be more firmly joined than in the case of the first preferred embodiment.

### Fourth Preferred Embodiment

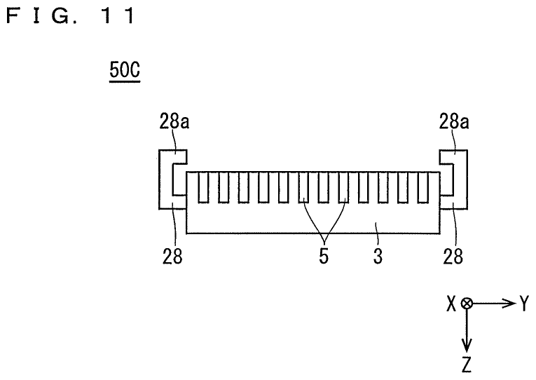

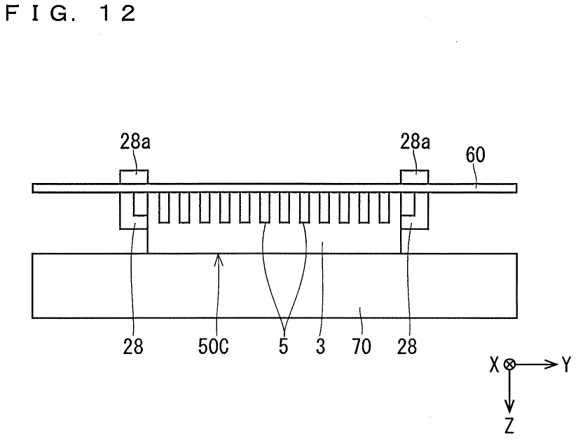

Next, a semiconductor device 50C according to a fourth preferred embodiment will be described. FIG. 11 is a side view of a state where the semiconductor device 50C according to the fourth preferred embodiment is turned upside down. FIG. 12 is a side view of a state where the semiconductor device 50C according to the fourth preferred embodiment is turned upside down and joined to the control board 60 and the heat sink 70. Note that in the fourth preferred embodiment, the same components as those described in the first to third preferred embodiments are denoted by the same reference signs, and description thereof is omitted.

As shown in FIGS. 11 and 12, in the fourth preferred embodiment, the semiconductor device 50C includes the pair of portions to be joined 28 instead of the pair of portions to be joined 8. The pins of the pair of portions to be joined 28, that is, the distal end portions of the pair of portions to be joined 28 are respectively provided with a pair of engagement portions 28a to be engaged with the holes (not shown) provided in the control board 60. The pair of engagement portions 28a extend in directions approaching the sealing resin 3 at the height position of the second main surface (the surface in the −Z direction) of the sealing resin 3. In order to improve simplicity at the time of mounting the semiconductor device 50C as compared with the case of the third preferred embodiment, the pair of portions to be joined 28 including the pair of engagement portions 28a are not made of copper but is made of a material having an excellent heat dissipation and being elastically deformable. As a result, the semiconductor device 50C and the control board 60 can be joined by fitting the pair of engagement portions 28a into the holes of the control board 60 in a single operation.

Next, a method of joining the control board 60 and the heat sink 70 to the semiconductor device 50C will be described.

As shown in FIG. 12, the heat sink 70 is disposed on the first main surface (the surface in the Z direction) of the sealing resin 3 via the heat dissipation grease, the resin sheet, or the like (not shown) as the heat transfer member, and the sealing resin 3 and the heat sink 70 are joined by a joining material (not shown) or the like.

The control board 60 to which the plurality of terminals 4, 5 are electrically connected is disposed on the second main surface (the surface in the −Z direction) of the sealing resin 3, and the distal end portions of the plurality of terminals 4, 5 and the pair of portions to be joined 28 are joined to the control board 60. Specifically, after the plurality of terminals 4, 5 are joined to the control board 60 by reflow soldering, the pair of portions to be joined 28 are joined to the control board 60 by inserting the pins into the holes (not shown) provided in the control board 60 and engaging the engagement portions 28a.

As described above, in the semiconductor device 50C according to the fourth preferred embodiment, each of the pins is provided with the engagement portion 28a that engages with the hole provided in the control board 60.

In addition, after the plurality of terminals 4, 5 are joined to the control board 60 by reflow soldering, the pair of portions to be joined 28 are joined to the control board 60 by inserting the pins into the holes provided in the control board 60 to engage the engagement portions 28a.

As in the case of the first preferred embodiment, it is possible to suppress peeling of the semiconductor device 50C from the control board 60 due to vibration or the like during operation of the system including the control board 60. In addition, since the semiconductor device 50C and the control board 60 can be joined by fitting the pair of engagement portions 28a into the holes of the control board 60 in a single operation, the mounting of the semiconductor device 50C can be simplified as compared with the case of the third preferred embodiment.

### Modifications of First to Fourth Preferred Embodiments

In the first to fourth preferred embodiments, the portions to be joined 8, 18, 28 are not limited to the pair, and a plurality of pairs of portions to be joined 8, 18, 28 may protrude from the third side surface (the surface in the Y direction) and the fourth side surface (the surface in the −Y direction) of the sealing resin 3.

Note that each of the preferred embodiments can be freely combined, and each of the preferred embodiments can be appropriately modified or omitted.

Hereinafter, various aspects of the present disclosure will be collectively described as appendixes.

### Appendix 1

A semiconductor device mounted on a control board, the semiconductor device including:
a semiconductor element;
a sealing resin that has a first main surface, a second main surface opposed to the first main surface, a first side surface connecting the first main surface and the second main surface, a second side surface connecting the first main surface and the second main surface and opposed to the first side surface, a third side surface connecting the first main surface and the second main surface and located between the first side surface and the second side surface, and a fourth side surface connecting the first main surface and the second main surface and opposed to the third side surface, and seals the semiconductor element; and
a plurality of terminals electrically connected to the semiconductor element, protruding from the first side surface and the second side surface of the sealing resin, and extending to a height position of the second main surface,
wherein a heat dissipation member is disposed on the first main surface of the sealing resin,
a control board to which the plurality of terminals are electrically connected is disposed on the second main surface of the sealing resin, and
the semiconductor device further includes a plurality of portions to be joined that protrude from the third side surface and the fourth side surface of the sealing resin, are joined to the control board, and are not electrically connected to the semiconductor element.

### Appendix 2

The semiconductor device according to Appendix 1, wherein the plurality of terminals extend in directions away from the sealing resin at the height position of the second main surface of the sealing resin.

### Appendix 3

The semiconductor device according to Appendix 1 or Appendix 2, wherein
a hole for screwing is provided in each of the plurality of portions to be joined, and
the plurality of portions to be joined are screwed to the control board to join the portions to be joined and the control board to each other.

### Appendix 4

The semiconductor device according to any one of Appendixes 1 to 3, wherein the plurality of portions to be joined extend to the height position of the second main surface of the sealing resin.

### Appendix 5

The semiconductor device according to Appendix 1 or Appendix 2, wherein a pin to be inserted into a hole provided in the control board is provided at a distal end portion of each of the plurality of portions to be joined.

### Appendix 6

The semiconductor device according to Appendix 5, wherein the pin is provided with an engagement portion that engages with the hole provided in the control board.

### Appendix 7

The semiconductor device according to any one of Appendixes 1 to 5, wherein materials of the plurality of terminals and the plurality of portions to be joined are same, but the plurality of portions to be joined are electrically floating.

### Appendix 8

The semiconductor device according to any one of Appendixes 1 to 7, wherein portions of the plurality of terminals protruding from the sealing resin are located at a height position between the first main surface and the second main surface of the sealing resin.

### Appendix 9

A method of mounting the semiconductor device according to Appendix 1 on the control board, wherein the plurality of portions to be joined are joined to the control board simultaneously with the plurality of terminals by reflow soldering.

### Appendix 10

A method of mounting the semiconductor device according to Appendix 3 on the control board, wherein after the plurality of terminals are joined to the control board by reflow soldering, the plurality of portions to be joined are joined to the control board by screwing.

### Appendix 11

A method of mounting the semiconductor device according to Appendix 5 on the control board, wherein after the plurality of terminals are joined to the control board by reflow soldering, the plurality of portions to be joined are joined to the control board by inserting the pins into the holes provided in the control board and then bending the pins, or soldering the pins to a ground terminal on the control board.

### Appendix 12

A method of mounting the semiconductor device according to Appendix 6 on the control board, wherein after the plurality of terminals are joined to the control board by reflow soldering, the plurality of portions to be joined are joined to the control board by inserting the pins into the holes provided in the control board and engaging the engagement portions.

While the disclosure has been shown and described in detail, the foregoing description is in all aspects illustrative and not restrictive. It is therefore understood that numerous modifications and variations can be devised.

What is claimed is:

1. A semiconductor device mounted on a control board, the semiconductor device comprising:
a semiconductor element;
a sealing resin that has a first main surface, a second main surface opposed to the first main surface, a first side surface connecting the first main surface and the second main surface, a second side surface connecting the first main surface and the second main surface and opposed to the first side surface, a third side surface connecting the first main surface and the second main surface and located between the first side surface and the second side surface, and a fourth side surface connecting the first main surface and the second main surface and opposed to the third side surface, and seals the semiconductor element; and
a plurality of terminals electrically connected to the semiconductor element, protruding from the first side surface and the second side surface of the sealing resin, and extending to a height position of the second main surface,
wherein a heat dissipation member is disposed on the first main surface of the sealing resin,
a control board to which the plurality of terminals are electrically connected is disposed on the second main surface of the sealing resin, and
the semiconductor device further comprises a plurality of portions to be joined that protrude from the third side surface and the fourth side surface of the sealing resin, are joined to the control board, and are not electrically connected to the semiconductor element.

2. The semiconductor device according to claim 1, wherein the plurality of terminals extend in directions away from the sealing resin at the height position of the second main surface of the sealing resin.

3. The semiconductor device according to claim 1, wherein
a hole for screwing is provided in each of the plurality of portions to be joined, and
the plurality of portions to be joined are screwed to the control board to join the portions to be joined and the control board to each other.

4. The semiconductor device according to claim 1, wherein the plurality of portions to be joined extend to the height position of the second main surface of the sealing resin.

5. The semiconductor device according to claim 1, wherein a pin to be inserted into a hole provided in the control board is provided at a distal end portion of each of the plurality of portions to be joined.

6. The semiconductor device according to claim 5, wherein the pin is provided with an engagement portion that engages with the hole provided in the control board.

7. The semiconductor device according to claim 1, wherein materials of the plurality of terminals and the plurality of portions to be joined are same, but the plurality of portions to be joined are electrically floating.

8. The semiconductor device according to claim 1, wherein portions of the plurality of terminals protruding from the sealing resin are located at a height position between the first main surface and the second main surface of the sealing resin.

9. A method of mounting the semiconductor device according to claim 1 on the control board, wherein the plurality of portions to be joined are joined to the control board simultaneously with the plurality of terminals by reflow soldering.

10. A method of mounting the semiconductor device according to claim 3 on the control board, wherein after the plurality of terminals are joined to the control board by reflow soldering, the plurality of portions to be joined are joined to the control board by screwing.

11. A method of mounting the semiconductor device according to claim 5 on the control board, wherein after the plurality of terminals are joined to the control board by reflow soldering, the plurality of portions to be joined are joined to the control board by inserting the pins into the holes provided in the control board and then bending the pins, or soldering the pins to a ground terminal on the control board.

12. A method of mounting the semiconductor device according to claim 6 on the control board, wherein after the plurality of terminals are joined to the control board by reflow soldering, the plurality of portions to be joined are joined to the control board by inserting the pins into the holes provided in the control board and engaging the engagement portions.
